(19) United States
(12) Patent Application Publication
(10) Pub. No.: US 2014/0335215 A1
(43) Pub. Date: Nov. 13, 2014

(54) BLANK FOR NANOIMPRINT MOLD, NANOIMPRINT MOLD, AND METHODS FOR PRODUCING SAID BLANK AND SAID NANOIMPRINT MOLD

(71) Applicant: ASAHI GLASS COMPANY, LIMITED, Chiyoda-ku (JP)

(72) Inventors: Kazuyuki Hayashi, Tokyo (JP); Kazunobu Maeshige, Tokyo (JP); Yasutomi Iwahashi, Tokyo (JP)

(73) Assignee: ASAHI GLASS COMPANY, LIMITED, Chiyoda-ku (JP)

(21) Appl. No.: 14/338,825

(22) Filed: Jul. 23, 2014

Related U.S. Application Data
(63) Continuation of application No. PCT/JP2013/050488, filed on Jan. 11, 2013.

(30) Foreign Application Priority Data
Jan. 23, 2012 (JP) 2012-010975

(51) Int. Cl. B29C 59/00; C23C 16/34; C23C 16/503; B29C 33/38; C23C 16/44

(52) U.S. Cl. CPC B29C 59/002; B29C 33/3842; C23C 16/4414; C23C 16/503; C23C 16/34
USPC 425/385; 216/11; 428/336; 204/192.15

(57) ABSTRACT

The present invention relates to a blank for a nanoimprint mold, comprising a glass substrate and a hard mask layer formed on the glass substrate, wherein the hard mask layer contains chromium (Cr) and nitrogen (N) and has a Cr content of 45 to 95 at %, an N content of 5 to 55 at % and a total content of Cr and N of 95 at % or more and the thickness of the hard mask layer is 1.5 nm or more and less than 5 nm.

### TECHNICAL FIELD

The present invention relates to a blank for a nanoimprint mold, which is used for the production of a nanoimprint mold employed in the semiconductor production and the like, a nanoimprint mold produced by using the blank for a nanoimprint mold, and production methods thereof.

### BACKGROUND ART

Heretofore, in the semiconductor industry, the photolithography process using visible light or ultraviolet light has been employed as a fine pattern transfer technique which is required in the formation of an integrated circuit composed of a fine pattern on a Si substrate or the like. However, in the case of photolithography process, the resolution limit of a pattern is about ½ of the exposure wavelength and is said to be about ¼ of the exposure wavelength even when an immersion method is used. It is estimated that even when an immersion method with an ArF laser (193 nm) is used, the resolution limit of a pattern is about 45 nm. With the rapid advance of miniaturization of a semiconductor device in recent years, EUV lithography that is an exposure technique employing EUV light having a wavelength further shorter than ArF laser is also being developed as a post-45 nm exposure technique in terms of resolution limit of a pattern.

On the other hand, as to the method for transferring a fine pattern onto a Si substrate or the like, a nanoimprint technique is recently being developed. The nanoimprint technique is a technique in which a glass substrate called mold and having a fine pattern formed thereon is put into close contact directly with a resist-coated Si substrate or the like to transfer the fine pattern (see Patent Document 1). This nanoimprint technique is prospective as a next-generation lithography technology, because the cost required for the production of a member used to transfer a fine pattern or for the exposure apparatus is low, compared with the ArF immersion method of EUV lithography. The member used for the transfer of a fine pattern is referred to as a transmissive mask in the case of ArF immersion method, as a reflective mask in the case of EUV lithography, and as a mold (nanoimprint mold) in the case of nanoimprint technique.

However, because the above-described nanoimprint technique is a transfer system of directly pressing the mold against a Si substrate or the like and is a pattern transfer at the same magnification, the production of the mold having formed therein a fine pattern must achieve the accuracy required of a semiconductor circuit pattern.

The nanoimprint mold is produced by forming a fine pattern on a glass substrate. The procedure for producing a conventional nanoimprint mold is described below by referring to FIG. 2.

A resist 20 is coated on a glass substrate 11 as illustrated in FIG. 2(a), and a master mold 40 having formed on the surface thereof a fine pattern is pressed against the resist 20 to transfer the fine pattern formed in the master mold 40 onto the resist 20 as illustrated in FIG. 2(b). The resist 20 is heat-cured or photocured in this state and thereafter, the master mold 40 is removed, as a result, a fine pattern by the resist 20 is formed on the glass substrate 11 as illustrated in FIGS. 2(c) and (d). Next, the glass substrate 11 is etched by dry etching process using a fluorine-based gas by employing, as a mask, the resist 20 having the fine pattern formed thereon, as a result, a fine pattern is formed on the glass substrate 11 as illustrated in FIG. 2(e). Subsequently, the resist 20 is removed by using an acid solution or an alkali solution, as a result, a nanoimprint mold 30 illustrated in FIG. 2(f), in which the fine pattern is formed on the glass substrate 11, is obtained.

As described above, the accuracy required of a semiconductor circuit pattern must be achieved in the production of a nanoimprint mold, but in the case of a process illustrated in FIGS. 2(a) to (f), where a resist is used as a mask in dry etching process using a fluorine-based gas, the etching resistance of the resist for the fluorine-based gas is low and therefore, when dry etching is carried out by using a fluorine-based gas, the etching selectivity between resist and glass substrate, represented by the following formula, is insufficient. Accordingly, the film thickness of the resist must be made thick (about 200 to 300 nm), but this makes it impossible to obtain sufficient resolution (see Patent Document 2).

(Etching selectivity)=(etching rate of glass substrate)/(etching rate of resist)

In Patent Document 2, a hard mask layer composed of a material having high etching selectivity to a substrate is used in place of a resist, whereby the thickness of the mask (hard mask layer) is reduced and sufficient resolution is obtained. In Patent Document 2, a layer composed of chromium (Cr film) is supposed to be preferable as a hard mask layer for a glass substrate (quartz substrate).

Also, Patent Document 3 discloses a production method of a template which works out to a mother mold in a pattern transfer method such as nanoimprinting using a mask blank in which an ultrathin film and a resist film are stacked on a base layer. In Patent Document 3, it is disclosed that the thickness of the ultrathin film is set to a minimum thickness at which the film can function as a mask at the time of etching the base layer and a three-dimensional pattern can be formed through etching of the base layer by using, as a mask, the ultrathin film having formed therein a pattern. Specifically, it is set to be from 5 nm to 40 nm.

### CITATION LIST

### Patent Literature

### Patent Document 1: JP-T-2007-521645

### Patent Document 2: JP-A-2010-219456

### Patent Document 3: Japanese Patent No. 4,619,043

### SUMMARY OF THE INVENTION

### Problems that the Invention is to Solve

However, it has been revealed that when a Cr film is formed as a hard mask layer as described in Patent Document 2, the adhesion to the glass substrate is poor due to a large tensile stress of the film. If the adhesion of the hard mask layer to the glass substrate is poor, the hard mask layer may be peeled from the glass substrate at the time of producing a nanoimprint mold and in turn, may not function as a mask in the dry etching process using a fluorine-based gas.

Also, if the tensile stress of the film is large, a pinhole may be produced in the hard mask layer. A pinhole produced in the hard mask layer may work out to a defect of the produced blank for a nanoimprint mold and thus, poses a problem.

Furthermore, even in the case of using a hard mask layer, as the pattern becomes finer in the future, the hard mask layer must be made thinner. For example, it is thought that when the pattern size is 20 nm or less, the thickness of the hard mask layer needs to be less than 5 nm, and the template for nanoimprinting described in Patent Document 3 cannot respond thereto.

In the case where the hard mask layer is made thin, the etching selectivity to the glass substrate must be high so as to obtain a predetermined dimensional accuracy by a fine pattern of the hard mask. For example, envisaging the formation of a pattern with a depth of 100 nm on a glass substrate, if the etching selectivity between glass substrate and hard mask layer is 5, a thickness of 20 nm is necessary as a hard mask layer, whereas if the etching selectivity between glass substrate and hard mask layer is 30, the thickness of the hard mask layer can be reduced to about 3.3 nm. In the case of Patent Document 3, the dry etching selectivity between SiO₂ constituting a quartz substrate and chromium nitride film formed as an ultrathin film is about 20:1 in Example 2 and with this etching selectivity, the thickness reduction of the hard mask layer can be only to 5 nm.

In order to solve the problems in those conventional techniques, an object of the present invention is to provide a blank for a nanoimprint mold, which contains a hard mask layer having characteristics that the etching selectivity to a glass substrate when carrying out dry etching using a fluorine-based gas is sufficiently high to enable thin film formation and at the same time, having a high adhesion to a glass substrate; a nanoimprint mold produced by using the blank for a nanoimprint mold; and production methods thereof.

### Means for Solving the Problems

As a result of intensive studies to attain the above-described object, the present inventors have found that a hard mask layer in which the etching selectivity to a glass substrate at the time of carrying out dry etching using a fluorine-based gas is sufficiently high and the adhesion to a glass substrate is excellent, can be obtained by forming a film containing Cr and N in a specific ratio (CrN film).

The present invention was made on the basis of the above findings and provides a blank for a nanoimprint mold, containing a glass substrate and a hard mask layer formed on the glass substrate, in which:

the hard mask layer contains chromium (Cr) and nitrogen (N), and has a Cr content of from 45 to 95 at %, an N content of from 5 to 55 at % and a total content of Cr and N of 95 at % or more, and the hard mask layer has a film thickness of 1.5 nm or more and less than 5 nm.

In the blank for a nanoimprint mold according to the present invention, it is preferred that the hard mask layer further contains hydrogen (H), and

the hard mask layer has the total content of Cr and N of from 95 to 99.9 at % and an H content of from 0.1 to 5 at %.

In the blank for a nanoimprint mold according to the present invention, it is preferred that the hard mask layer has a crystal state of amorphous.

In the blank for a nanoimprint mold according to the present invention, it is preferred that the hard mask layer has an etching selectivity represented by (etching rate of glass substrate)/(etching rate of hard mask layer) is 30 or more.

In the blank for a nanoimprint mold according to the present invention, it is preferred that the glass substrate is made of a dopant-free or dopant-containing quartz glass.

Further, the present invention provides a nanoimprint mold produced by using the blank for a nanoimprint mold of the present invention.

In addition, the present invention provides a method for producing a blank for a nanoimprint mold, containing a glass substrate and a hard mask layer formed on the glass substrate, in which:

the hard mask layer contains chromium (Cr) and nitrogen (N), and has a Cr content of from 45 to 95 at %, an N content of from 5 to 55 at % and a total content of Cr and N of 95 at % or more, and

the method contains forming the hard mask layer on the glass substrate by performing a sputtering process using a Cr target in an inert gas atmosphere containing argon (Ar) and nitrogen (N₂).

In addition, the present invention provides a method for producing a nanoimprint mold by using the mask blank for a nanoimprint mold of the present invention, the method containing a step of etching the hard mask layer of the mask blank for a nanoimprint mold by a dry etching process using a chlorine-based gas to form a pattern on the hard mask layer, and a step of etching the glass substrate by a dry etching process using a fluorine-based gas by employing, as a mask, the pattern formed on the hard mask layer.

Furthermore, the present invention provides a nanoimprint mold produced by the production method for a nanoimprint mold described of the present invention.

### Advantage of the Invention

The blank for an imprint mold of the present invention has an excellent adhesion to the glass substrate and a sufficiently high etching selectivity to the glass substrate when carrying out dry etching using a fluorine-based gas, by using a film containing Cr and N in a specific ratio as a hard mask layer at forming a fine pattern on the glass substrate. Therefore, it is expected that the hard mask layer can be reduced in its thickness and a nanoimprint mold having higher resolution can be produced.

### BRIEF DESCRIPTION OF THE DRAWINGS

FIGS. 1(a) to (f) are figures illustrating the procedure for producing a nanoimprint mold by using the blank for a nanoimprint mold of the present invention.

FIGS. 2(a) to (f) are figures illustrating the procedure for producing a nanoimprint mold by using a conventional blank for a nanoimprint mold.

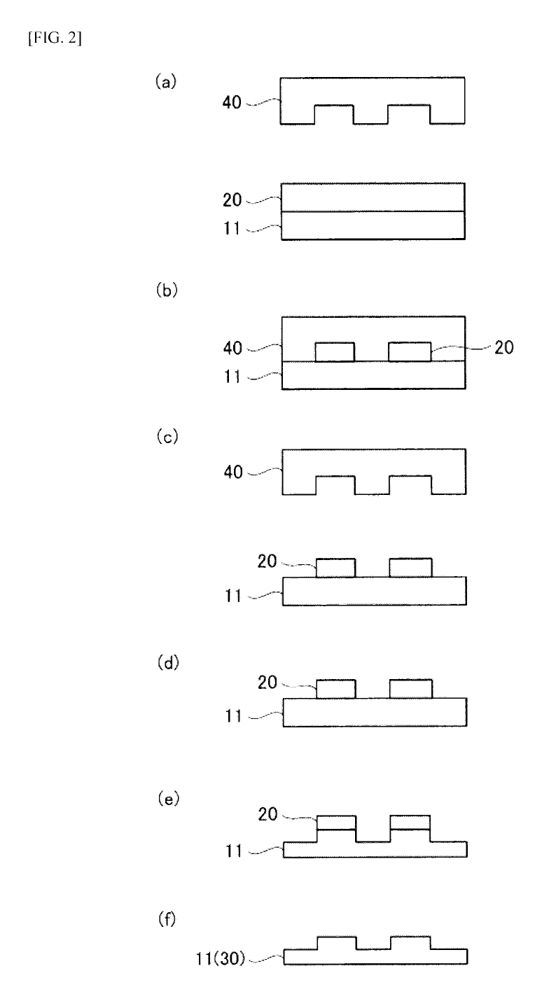

### MODE FOR CARRYING OUT THE INVENTION

The blank for a nanoimprint mold of the present invention is described below.

The blank for a nanoimprint mold of the present invention contains a glass substrate and a hard mask layer formed on the glass substrate. Individual configurations of the blank for a nanoimprint mold of the present invention are described below.

### <Glass Substrate>

The glass substrate is required to satisfy the properties as a substrate for a nanoimprint mold.

If a nanoimprint mold changes the shape due to a temperature change at the time of transferring a fine pattern, the positional accuracy of the fine pattern transferred is reduced. For this reason, the glass substrate for a nanoimprint mold is required to hardly cause shape change due to temperature change at the time of transferring a fine pattern. In order to achieve this, the glass substrate is required to have a low coefficient of thermal expansion in the temperature region at the time of transferring a fine pattern.

Specifically, the coefficient of thermal expansion at 20 to 35° C. is preferably 0±6×10⁻⁷/° C., and more preferably 0±5×10⁻⁷/° C.

The substrate for a nanoimprint mold is required to have a surface on which a fine pattern is formed having excellent in smoothness and flatness. Specifically, it is preferred to have a smooth surface with a surface roughness (rms) of 0.15 nm or less and a flatness of 500 nm or less. In addition, the surface opposite to the surface on which a fine pattern is formed is also preferably excellent in flatness and preferably has a flatness of 3 μm or less.

It is also required to have excellent resistance to a cleaning solution used for cleaning or the like that is carried out at the time of producing a nanoimprint mold. Furthermore, at the time of transferring a pattern onto a resist coated on a Si substrate, photocuring is performed by using, for example, light with a wavelength of 300 to 400 nm and therefore, it needs to have a certain degree of transmittance at the wavelength above. Specifically, it preferably has a transmittance of 60% or more for light with a wavelength of 300 to 400 nm.

Preferable examples of the glass substrate satisfying the above-described properties include quartz glass. As the quartz glass, in addition to quartz glass not containing a dopant, quartz glass into which a dopant such as TiO₂ is incorporated for the purpose of decreasing the coefficient of thermal expansion, may also be used.

Among others, quartz glass containing TiO₂ as a dopant (hereinafter, referred to as “SiO₂—TiO₂-based glass”) is preferred. The TiO₂ concentration in the SiO₂—TiO₂-based glass is preferably from 3 to 10 wt %.

The size, thickness, etc. of the glass substrate are appropriately determined according to design values and the like of the nanoimprint mold (blank for a nanoimprint mold). In Examples later, a SiO₂—TiO₂-based glass having an outer shape of a 6-inch (152 mm) square and a thickness of 0.25 inch (6.3 mm) was used.

### <Hard Mask Layer>

The hard mask layer formed on the glass substrate is required to ensure a high etching selectivity to the glass substrate at the time of carrying out dry etching using a fluorine-based gas.

Also, the hard mask layer is required to exhibit excellent adhesion to the glass substrate.

Furthermore, since the production of a nanoimprint mold according to the later-described procedure involves etching the hard mask layer by dry etching process using a chlorine-based gas, the hard mask layer is required to ensure a high etching rate at the time of carrying out etching using a chlorine-based gas.

In addition, the surface of the hard mask layer is preferably excellent in smoothness so as to enhance the dimensional accuracy of a pattern formed on the hard mask layer when producing a nanoimprint mold according to the later-described procedure.

For satisfying these requirements, the hard mask layer of the present invention contains chromium (Cr) and nitrogen (N) in the following specific ratio.

The hard mask layer in the present invention has a Cr content of 45 to 95 at %.

If the Cr content is less than 45 at %, the film stress (compressive stress) of the hard mask layer is increased whereby the adhesion of the hard mask layer to the glass substrate is decreased. Also, it is formed as a film having a crystal structure and therefore, the smoothness of the hard mask layer surface is reduced.

On the other hand, if the Cr content exceeds 95 at %, the film stress (tensile stress) of the hard mask layer is increased whereby the adhesion of the hard mask layer to the glass substrate is decreased. Also, it is formed as a film having a crystal structure and therefore, the smoothness of the hard mask layer surface is reduced.

The Cr content is preferably from 50 to 95 at %, more preferably from 50 to 90 at %, and still more preferably from 55 to 90 at %.

The hard mask layer in the present invention has an N content of 5 to 55 at %.

If the N content is less than 5 at %, the film stress (tensile stress) of the hard mask layer is increased whereby the adhesion of the hard mask layer to the glass substrate is decreased. Also, it is formed as a film having a crystal structure and therefore, the smoothness of the hard mask layer surface is reduced.

On the other hand, if the N content exceeds 55 at %, the film stress (compressive stress) of the hard mask layer is increased whereby the adhesion of the hard mask layer to the glass substrate is decreased. Also, it is formed as a film having a crystal structure and therefore, the smoothness of the hard mask layer surface is reduced.

The N content is preferably from 5 to 50 at %, more preferably from 10 to 50 at %, and still more preferably from 10 to 45 at %.

The hard mask layer of the present invention has a total content of Cr and N of 95 at % or more. If the total content of Cr and N is less than 95 at %, there arises a problem that, for example, a sufficient etching selectivity to the glass substrate cannot be ensured, or the film is crystallized.

The hard mask layer of the present invention may contain other elements not adversely affecting the hard mask layer as long as the total content of Cr and N is 95 at % or more. Specific examples of other elements include hydrogen (H) and oxygen (O). In the case where the hard mask layer of the present invention contains such other elements, the total content of Cr and N in the hard mask layer may be, for example, from 95 to 99.9 at %, and the content of other elements (e.g., H) may be from 0.1 to 5 at %.

For example, in the case of containing hydrogen, effects such as “can suppress crystallinity” and “can reduce surface roughness” can be obtained.

Thanks to the above-described configuration, the hard mask layer of the present invention ensures a high etching selectivity to the glass substrate at the time of carrying out dry etching using a fluorine-based gas.

Specifically, the etching selectivity determined by the following formula is preferably 30 or more.

(Etching selectivity)=(etching rate of glass substrate)/(etching rate of hard mask layer)

The etching selectivity is preferably 35 or more, more preferably 40 or more, and still more preferably 45 or more.

Also, thanks to the above-described configuration, the hard mask layer of the present invention is reduced in the film stress and ensures excellent adhesion to the glass substrate.

The film stress of the hard mask layer varies depending on the film thickness of the hard mask layer, but in the case where the film thickness is in the later-described preferable range, the absolute value of the film stress is preferably 200 MPa or less, more preferably 175 MPa or less, and still more preferably 150 MPa or less.

Thanks to the above-described configuration, the crystal state of the hard mask layer of the present invention is likely to become amorphous, and this is preferred. In the present description, the expression “crystal state is amorphous” encompasses a type having a microcrystalline structure, in addition to a type having an amorphous structure having no crystal structure at all.

The hard mask layer is a film having an amorphous structure or a film having a microcrystalline structure, whereby the smoothness of the hard mask layer surface is enhanced. Specifically, the surface roughness (rms) of the hard mask layer becomes, for example, 0.5 nm or less.

Here, the surface roughness of the hard mask layer can be measured by using an atomic force microscope.

If the surface roughness of the hard mask layer is large, the dimensional accuracy of a pattern formed on the hard mask layer may be deteriorated due to the effect of line edge roughness at the time of dry-etching the hard mask layer by using a chlorine-based gas when producing a nanoimprint mold according to the later-described procedure. If the dimensional accuracy of a pattern formed on the hard mask layer is deteriorated, a problem arises at the time of carrying out dry etching process using a fluorine-based gas by employing, as a mask, the hard mask layer having the pattern formed thereon, because the dimensional accuracy of a fine pattern formed on the glass substrate deteriorates. As the pattern is finer, the influence of the line edge roughness is remarkable. Therefore, the hard mask layer surface is preferably smooth.

When the surface roughness (rms) of the hard mask layer is 0.5 nm or less, the hard mask layer surface is sufficiently smooth and therefore, the dimensional accuracy of a pattern formed on the hard mask layer is kept from deteriorating due to the effect of line edge roughness. The surface roughness (rms) of the hard mask layer is preferably 0.45 nm or less, and more preferably 0.4 nm or less.

Whether the crystal state of the hard mask layer is amorphous, that is, has an amorphous structure or a microcrystalline structure, can be confirmed by X-ray diffraction (XRD) method. When the crystal state of the hard mask layer is an amorphous structure or a microcrystalline structure, a sharp peak is not observed in the diffraction peaks obtained by XRD measurement.

If the hard mask layer is a film having a crystal structure, also for the reason that, for example, etching proceeds selectively only in a specific crystal orientation at the time of etching the hard mask layer by using a chlorine-based gas when producing a nanoimprint mold according to the later-described procedure, the line edge roughness of a pattern formed on the hard mask layer may be increased whereby the dimensional accuracy of the pattern deteriorates.

For this reason as well, the crystal state of the hard mask layer is preferably amorphous.

In addition, since the hard mask layer is etched by using a chlorine-based gas by employing, as a mask, a resist having formed thereon a fine pattern when producing a nanoimprint mold according to the later-described procedure, the hard mask layer preferably ensures a high etching selectivity between the hard mask layer and the resist at the time of carrying out the dry etching using a chlorine-based gas.

Here, the etching selectivity between the hard mask layer and the resist is represented by the following formula:

(Etching selectivity)=(etching rate of hard mask layer)/(etching rate of resist)

Specifically, the etching selectivity determined by the formula above is preferably 0.10 or more, more preferably 0.11 or more, and still more preferably 0.12 or more.

The film thickness of the hard mask layer is from 1.5 nm to less than 5 nm. If the film thickness of the hard mask layer is less than 1.5 nm, the glass substrate may not be etched in a predetermined amount depending on the etching selectivity to the glass substrate at the time of carrying out dry etching using a fluorine-based gas.

On the other hand, if the film thickness of the hard mask layer is large, the thickness of a resist coated on the hard mask layer is increased, and the dimensional accuracy of a pattern formed on the hard mask layer is deteriorated when producing a nanoimprint mold according to the later-described procedure. A hard mask layer having a thickness of 5 nm or more cannot respond to the miniaturization of the pattern size to 20 nm or less.

In the hard mask layer of the present invention, the etching selectivity represented by (etching rate of glass substrate)/(etching rate of hard mask layer) is high (preferably 30 or more), so that the above-described ultrathin film can be formed.

The hard mask layer in the present invention can be formed by performing a known film deposition method, for example, a sputtering method such as magnetron sputtering method and ion beam sputtering method. In the case of forming the hard mask layer containing Cr and N by a sputtering method, a sputtering method using a Cr target may be carried out in an atmosphere containing at least one inert gas of helium (He), argon (Ar), neon (Ne), krypton (Kr) or xenon (Xe), and nitrogen (N₂). In the case of employing a magnetron sputtering method, specifically, it may be carried out, for example, under the following film deposition conditions.

Sputtering gas: a mixed gas of Ar and N₂ (N₂ gas concentration: from 1 to 80 vol %, preferably from 5 to 75 vol %; Ar gas concentration: from 20 to 99 vol %, preferably from 25 to 95 vol %; gas pressure: from 1.0×10⁻¹ Pa to 50×10⁻¹ Pa, preferably from 1.0×10⁻¹ Pa to 40×10⁻¹ Pa, more preferably from 1.0×10⁻¹ Pa to 30×10⁻¹ Pa)

Input power: from 30 to 3,000 W, preferably from 100 to 3,000 W, more preferably from 500 to 3,000 W

Film deposition rate: from 0.5 to 60 nm/min, preferably from 1.0 to 45 nm/min, more preferably from 1.5 to 30 nm/min

When another inert gas is used instead of Ar, the concentration of the inert gas is set to the same concentration range as the above-described Ar gas concentration. Also, in the case of using several kinds of inert gases, the total concentration of the inert gases is set to the same concentration range as the above-described Ar gas concentration.

Also, the sputtering gas may contain hydrogen (H₂) or oxygen (O₂) at a concentration of 10 vol % or less, preferably 5 vol % or less, and more preferably 3 vol % or less, in addition to the inert gas and nitrogen (N₂).

For example, in the case of forming a hard mask layer containing Cr, N and H, a sputtering method using a Cr target may be carried out in an atmosphere containing at least one inert gas of helium (He), argon (Ar), neon (Ne), krypton (Kr) or xenon (Xe), nitrogen (N₂) and hydrogen (H₂). In the case of using a magnetron sputtering method, specifically, it may be carried out, for example, under the following film deposition conditions.

Sputtering gas: a mixed gas of Ar, N₂ and H₂ (H₂ gas concentration: from 1 to 10 vol %, preferably from 1 to 3 vol %; N₂ gas concentration: from 4 to 85 vol %, preferably from 5 to 75 vol %; Ar gas concentration: from 5 to 95 vol %, preferably from 22 to 94 vol %; gas pressure: from 1.0×10⁻¹ Pa to 50×10⁻¹ Pa, preferably from 1.0×10⁻¹ Pa to 40×10⁻¹ Pa, more preferably from 1.0×10⁻¹ Pa to 30×10⁻¹ Pa)

Input power: from 30 to 3,000 W, preferably from 100 to 3,000 W, more preferably from 500 to 3000 W

Film deposition rate: from 0.5 to 60 nm/min, preferably from 1.0 to 45 nm/min, more preferably from 1.5 to 30 nm/min

The procedure for producing a nanoimprint mold by using the blank for a nanoimprint mold of the present invention is described below.

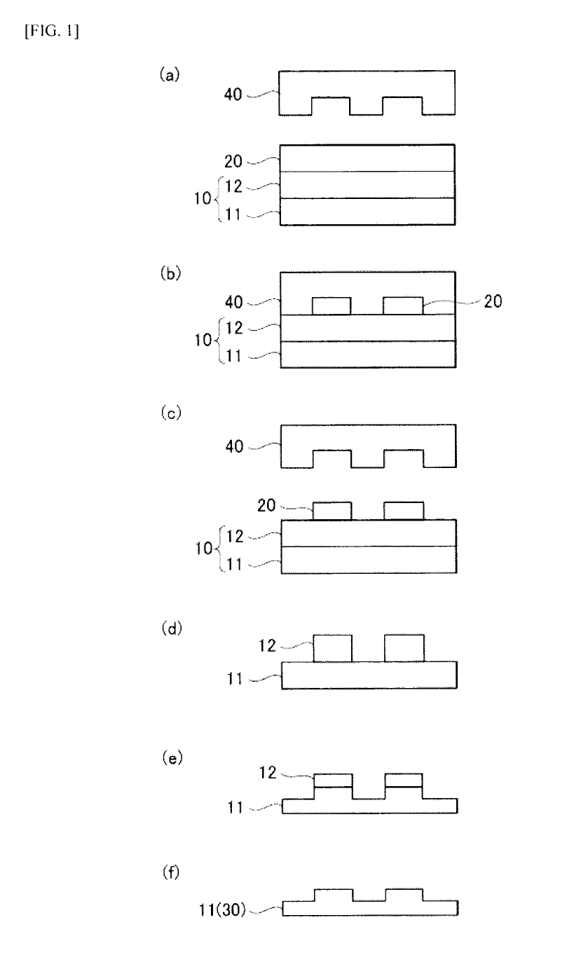

FIGS. 1(a) to (f) are figures illustrating the procedure for producing a nanoimprint mold by using the blank for a nanoimprint mold of the present invention.

As illustrated in FIG. 1(a), a resist 20 is coated on a hard mask layer 12 of the blank 10 for a nanoimprint mold of the present invention in which the hard mask layer 12 is formed on a glass substrate 11. Here, the resist may either a negative resist or a positive resist.

Next, a master mold 40 having formed on the surface thereof a fine pattern is pressed against the resist 20 to transfer the fine pattern formed in the master mold 40 onto the resist 20 as illustrated in FIG. 1(b). The resist 20 is heat-cured or photocured in this state and thereafter, the master mold 40 is removed, as a result, a fine pattern by the resist 20 is formed on the hard mask layer 12 as illustrated in FIG. 1(c).

Subsequently, the hard mask layer 12 is etched by dry etching process using a chlorine-based gas by employing, as a mask, the resist 20 having formed thereon the fine pattern, and the resist 20 is then removed with an acid solution or an alkali solution, as a result, a fine pattern is formed on the hard mask layer 12 as illustrated in FIG. 1(d). The chlorine-based gas used here includes, for example, Cl₂, BCl₃, HCl, a mixed gas thereof, and a gas obtained by incorporating a rare gas (e.g., He, Ar, Xe) as an additive gas to the gas above.

Furthermore, the glass substrate 11 is etched by dry etching process using a fluorine-based gas by employing, as a mask, the hard mask layer 12 having formed thereon the fine pattern, as a result, a fine pattern is formed on the glass substrate 11 as illustrated in FIG. 1(e). The fluorine-based gas used here includes, for example, CₓF_{y} (e.g., CF₄, C₂F₆, C₃F₈), CHF₃, a mixed gas thereof, and a gas obtained by incorporating a rare gas (e.g., He, Ar, Xe) as an additive gas into the gas above.

Thereafter, the hard mask layer 12 is removed by dry etching process using a chlorine-based gas, as a result, a nanoimprint mold 30 as illustrated in FIG. 1(f), in which the fine pattern is formed on the glass substrate 11, is obtained.

### EXAMPLES

The present invention is described in greater detail below by referring to Examples, but the present invention should not be construed as being limited thereto.

### Example 1

In this Example, a blank 10 for a nanoimprint mold illustrated in FIG. 1(a), that is, a blank for a nanoimprint mold, in which a hard mask layer 12 is formed on a glass substrate 11, was produced.

As the glass substrate 11, a SiO₂—TiO₂-based glass substrate (outer shape: a 6-inch (152.4 mm) square, thickness: 6.3 mm) was used.

### Formation of Hard Mask Layer 12 (CrN Film)

A CrN film as the hard mask layer 12 was deposited on the glass substrate 11 surface by using a magnetron sputtering method. Specifically, after vacuumizing the inside of the deposition chamber to 1×10⁻⁴ Pa or less, magnetron sputtering was performed by using a Cr target in a mixed gas atmosphere of Ar and N₂ to form a hard mask layer 12

(CrN film) having a thickness of 4 nm. The film deposition conditions of the hard mask layer 12 (CrN film) were as follows.

Target: Cr target

Sputtering gas: a mixed gas of Ar and N₂ (Ar: 58.2 vol %, N₂: 41.8 vol %, gas pressure: 0.1 Pa)

Input power: 1,500 W

Film deposition rate: 10.8 nm/min

Film thickness: 4 nm

### Compositional Analysis of Hard Mask Layer 12 (CrN Film)

The composition of the hard mask layer 12 formed by the procedure above was measured by using an X-ray electron spectrometer (manufactured by PERKIN ELEMER-PHI). The compositional ratio (at %) of the hard mask layer 12 was Cr:N=86.0:14.0.

### Film Stress of Hard Mask Layer 12 (CrN Film)

The film stress of the hard mask layer 12 formed by the procedure above was measured according to the following procedure.

The curvature radius of the blank 10 for a nanoimprint mold was measured by using a laser interferometer, and the film stress of the hard mask layer 12 was calculated by using the Young's modulus and Poisson ratio of the glass substrate 11 and the film thickness of the hard mask layer 12. As a result, it was confirmed that a compressive stress of −98 MPa is produced in the hard mask layer 12.

### Crystal State of Hard Mask Layer 12 (CrN Film)

The crystal state of the hard mask layer 12 was verified by an X-ray diffractometer (manufactured by RIGAKU). A sharp peak was not observed in the obtained diffraction peaks and therefore, the crystal state of the hard mask layer 12 was confirmed to be an amorphous structure or a microcrystalline structure.

### Surface Roughness of Hard Mask Layer 12 (CrN Film)

The surface roughness of the hard mask layer 12 was measured by using an atomic force microscope (SPI-3800 manufactured by SII) in dynamic force mode. The region for measurement of surface roughness was 1 μm×1 μm, and SI-DF40 (manufactured by SII) was used as a cantilever. The surface roughness (rms) of the hard mask layer 12 was 0.4 nm.

### Adhesion of Hard Mask Layer 12 (CrN Film)

On the surface of the hard mask layer 12 formed by the procedure above, a grid pattern was formed in accordance with the cross-cut adhesion test method described in JIS K5400 (1990) to prepare a test piece. Thereafter, a pressure-sensitive adhesive tape (cellophane tape produced by NICHIBAN Co., Ltd.) was adhered to the grid pattern of the test piece and then peeled off by quickly pulling in the direction of 90°, and whether peeling-off occurs in 100 squares or not was tested. As a result, peeling-off of squares did not occur.

### Etching Properties of Hard Mask Layer 12 (CrN Film)

The etching properties were evaluated by the following method instead of evaluating etching properties by using the blank 10 for an imprint mold produced by the procedure above.

A blank 10 for an imprint mold, where a hard mask layer 12 (CrN film) was deposited to 100 nm on a glass substrate 11 under the same conditions as above, was produced as a sample, and etched by ICP-RIE (inductively coupled plasma reactive ion etching) process using a chlorine-based gas or a fluorine-based gas. The etching conditions were shown below.

### Chlorine-Based Gas Etching Conditions:

Etching Condition: Cl₂+He (Cl₂: 4 sccm, He: 16 sccm)

Etching pressure: 0.3 Pa

Antenna Power: 100 W

Bias Power: 40 W

### Fluorine-Based Gas Etching Conditions:

Etching gas: CF₄+He (CF₄: 50 sccm, He: 50 sccm)

Etching pressure: 1.0 Pa

Antenna Power: 60 W

Bias Power: 20 W

First, the etching rate of the hard mask layer 12 in the dry etching process using a chlorine-based gas that is employed at the time of etching the hard mask layer 12 was examined.

As a result of etching the hard mask layer 12 (CrN film) under the above-described chlorine-based gas etching conditions, the etching rate was 15.6 nm/min, and this reveals that sufficient etching can be achieved by dry etching process using a chlorine-based gas.

Next, the etching rate of the hard mask layer 12 in the dry etching process using a fluorine-based gas that is employed at the time of etching the glass substrate was examined.

As a result of etching the hard mask layer 12 (CrN film) under the above-described fluorine-base gas etching conditions, the etching rate was 0.6 nm/min. On the other hand, when the SiO₂—TiO₂-based glass substrate without a hard mask layer 12 was etched under the same conditions, the etching rate was 35 nm/min. With respect to the dry etching process using a fluorine-based gas, the etching selectivity of the SiO₂—TiO₂-based glass substrate to the hard mask layer 12 (CrN film) was calculated by the following formula:

(Etching selectivity)=(etching rate of SiO₂—TiO₂-based glass)/(etching rate of CrN film)

The etching selectivity calculated by the formula above was 58, and it could be confirmed that a sufficient etching selectivity is ensured.

Furthermore, when a case of etching the SiO₂—TiO₂-based glass by 100 nm for the production of a nanoimprint mold is envisaged, the required film thickness of the hard mask layer 12 (CrN film) calculated from the etching selectivity above becomes 1.7 nm, and it is apparent that the film with a thickness thinner than in the conventional resist process sufficiently functions as a hard mask layer.

### Example 2

Example 2 is the same as Example 1 except that a CrNH film was formed as the hard mask layer 12 according to the following procedure. Formation of Hard Mask Layer 12 (CrNH)

A CrNH film as the hard mask layer 12 was deposited on the substrate 11 surface by using a magnetron sputtering method. Specifically, after vacuumizing the inside of the deposition chamber to 1×10⁻⁴ Pa or less, magnetron sputtering was performed by using a Cr target in a mixed gas atmosphere of Ar, N₂ and H₂ to form a hard mask layer 12 (CrNH film) having a thickness of 4 nm. The film deposition conditions of the hard mask layer 12 (CrNH film) were as follows.

Target: Cr target

Sputtering gas: a mixed gas of Ar, N₂ and H₂ (Ar: 58.2 vol %, N₂: 40 vol %, H₂: 1.8 vol %, gas pressure: 0.1 Pa)

Input power: 1,500 W

Film deposition rate: 10.8 nm/min

Film thickness: 4 nm

### Compositional Analysis of Hard Mask Layer 12 (CrNH Film)

The composition of the hard mask layer 12 was measured by using an X-ray electron spectrometer by the same procedure as in Example 1. The compositional ratio (at %) of the hard mask layer 12 was Cr:N:H=86.0:13.7:0.3.

### Film Stress of Hard Mask Layer 12 (CrNH Film)

The film stress of the hard mask layer 12 formed by the procedure above was measured according to the same procedure as in Example 1, as a result, it was confirmed that a tensile stress of +58 MPa is produced in the hard mask layer 12.

### Crystal State of Hard Mask Layer 12 (CrNH Film)

The crystal state of the hard mask layer 12 was verified according to the same procedure as in Example 1. A sharp peak was not observed in the obtained diffraction peaks and therefore, the crystal state of the hard mask layer 12 was confirmed to be an amorphous structure or a microcrystalline structure.

### Surface Roughness of Hard Mask Layer 12 (CrNH Film)

The surface roughness of the hard mask layer 12 was evaluated in the same manner as in Example 1, as a result, the surface roughness (rms) of the hard mask layer 12 was 0.25 nm.

### Adhesion of Hard Mask Layer 12 (CrNH Film)

The adhesion of the hard mask layer 12 was evaluated in the same manner as in Example 1, as a result, peeling-off of squares did not occur, and it could be confirmed that sufficient adhesion can be achieved.

### Etching Properties of Hard Mask Layer 12 (CrNH Film)

The etching properties of the hard mask layer 12 in dry etching process using a fluorine-based gas were evaluated in the same manner as in Example 1. The etching rate of the hard mask layer 12 (CrNH film) was 0.7 nm/min. Since the etching rate of the SiO₂—TiO₂-based glass substrate without a hard mask layer 12 is 35 nm/min, the etching selectivity is 50, and it could be confirmed that a sufficient etching selectivity is ensured.

Furthermore, when a case of etching the SiO₂—TiO₂-based glass by 100 nm for the production of a nanoimprint mold is envisaged, the required film thickness of the hard mask layer 12 (CrNH film) calculated from the etching selectivity above becomes 2.0 nm, and it is apparent that the film with a thickness thinner than in the conventional resist process sufficiently functions as a hard mask layer.

### Comparative Example 1

Comparative Example 1 was carried out according to the same procedure as in Example 1 except that on the glass substrate 11, a resist was coated in place of a hard mask layer 12. In Comparative Example 1, only etching properties are discussed.

In Comparative Example 1, a chemical amplification positive resist for electron beam lithography was coated as a resist on a SiO₂—TiO₂-based glass substrate to a thickness of 300 nm by a spin coating method, and after the coating, post-baking at 110° C. was carried out.

The SiO₂—TiO₂-based glass substrate with the resist formed as above was examined for the etching rate in dry etching process using a fluorine-based gas in the same manner as in Example 1.

The etching rate of the resist was 77 nm/min. Since the etching rate of the SiO₂—TiO₂-based glass substrate without a resist is 35 nm/min under the same conditions, the etching selectivity is 0.5, and a sufficient etching selectivity could not be ensured. In this case, when a case of etching the SiO₂—TiO₂-based glass by 100 nm for the production of a nanoimprint mold is envisaged, the required film thickness of the resist calculated from the etching selectivity above becomes 200 nm.

### Comparative Example 2

This Comparative Example is the same as Example 1 except that a Cr film was formed as the hard mask layer 12 according to the following procedure.

### Formation of Hard Mask Layer 12 (Cr Film)

A Cr film as the hard mask layer 12 was deposited on the substrate 11 surface by using a magnetron sputtering method. Specifically, after vacuumizing the inside of the deposition chamber to 1×10⁻⁴ Pa or less, magnetron sputtering was performed by using a Cr target in an Ar gas atmosphere to form a hard mask layer 12 (Cr film) having a thickness of 5 nm. The film deposition conditions of the hard mask layer 12 (Cr film) were as follows.

Target: Cr target

Sputtering gas: an Ar gas (Ar: 100 vol %, gas pressure: 0.1 Pa)

Input power: 1,500 W

Film deposition rate: 18 nm/min

Film thickness: 5 nm

### Compositional Analysis of Hard Mask Layer 12 (Cr Film)

The composition of the hard mask layer 12 was measured by using an X-ray electron spectrometer by the same procedure as in Example 1. The compositional ratio (at %) of the hard mask layer 12 was Cr=100.0.

### Film Stress of Hard Mask Layer 12 (Cr Film)

The film stress of the hard mask layer 12 was measured by the same method as in Example 1.

It was confirmed that a very large tensile stress of +1,000 MPa is produced in the hard mask layer 12.

### Crystal State of Hard Mask Layer 12 (Cr Film)

The crystal state of the hard mask layer 12 was verified by the same method as in Example 1. A sharp peak was observed in the obtained diffraction peaks and therefore, the hard mask layer 12 was confirmed to have a crystal structure.

### Surface Roughness of Hard Mask Layer 12 (Cr Film)

The surface roughness of the hard mask layer 12 was evaluated in the same manner as in Example 1, as a result, the surface roughness (rms) of the hard mask layer 12 was 0.5 nm.

### Adhesion of Hard Mask Layer 12 (Cr Film)

The adhesion of the hard mask layer 12 was evaluated in the same manner as in Example 1, as a result, peeling-off of squares occurred, revealing that the adhesion is insufficient. That is, it was confirmed that the Cr film cannot sufficiently function as a hard mask layer of the blank for an imprint mold.

### Comparative Example 3

This Comparative Example is the same as Example 1 except that a CrN film having an N content of less than 5% was formed as the hard mask layer 12 according to the following procedure.

### Formation of Hard Mask Layer 12 (CrN Film)

A CrN film as the hard mask layer 12 was deposited on the substrate 11 surface by using a magnetron sputtering method. Specifically, after vacuumizing the inside of the deposition chamber to 1×10⁻⁴ Pa or less, magnetron sputtering was performed by using a Cr target in a mixed gas atmosphere of Ar and N₂ to form a hard mask layer 12 (CrN film) having a thickness of 5 nm. The film deposition conditions of the hard mask layer 12 (CrN film) were as follows.

Target: Cr target

Sputtering gas: a mixed gas of Ar and N₂ (Ar: 90 vol %, N₂: 10 vol %, gas pressure: 0.1 Pa)

Input power: 1,500 W

Film deposition rate: 12 nm/min

Film thickness: 5 nm

### Compositional Analysis of Hard Mask Layer 12 (CrN Film)

The composition of the hard mask layer 12 was measured by using an X-ray electron spectrometer by the same procedure as in Example 1. The compositional ratio (at %) of the hard mask layer 12 was Cr:N=96.0:4.0.

### Stress of Hard Mask Layer 12 (CrN Film)

The stress of the hard mask layer 12 was measured by the same method as in Example 1. It was confirmed that a very large tensile stress of +960 MPa is produced in the hard mask layer 12.

### Crystal State of Hard Mask Layer 12 (CrN Film)

The crystal state of the hard mask layer 12 was verified by the same method as in Example 1. A sharp peak was observed in the obtained diffraction peaks and therefore, the hard mask layer was confirmed to have a crystal structure.

### Surface Roughness of Hard Mask Layer 12 (CrN Film)

The surface roughness of the hard mask layer 12 was evaluated in the same manner as in Example 1, as a result, the surface roughness (rms) of the hard mask layer 12 was 0.6 nm.

### Adhesion of Hard Mask Layer 12 (CrN Film)

The adhesion of the hard mask layer 12 was evaluated in the same manner as in Example 1, as a result, peeling-off of squares occurred, revealing that the adhesion is insufficient. That is, it was confirmed that the film cannot sufficiently function as a hard mask layer of the blank for an imprint mold.

### Comparative Example 4

This Comparative Example is the same as Example 1 except that a CrN film having an N content of more than 55% was formed as the hard mask layer 2 according to the following procedure.

### Formation of Hard Mask Layer 12 (CrN Film)

A CrN film as the hard mask layer 12 was deposited on the substrate 11 surface by using a magnetron sputtering method. Specifically, after vacuumizing the inside of the deposition chamber to 1×10⁻⁴ Pa or less, magnetron sputtering was performed by using a Cr target in a mixed gas atmosphere of Ar and N₂ to form a hard mask layer 12 (CrN film) having a thickness of 5 nm. The film deposition conditions of the hard mask layer 12 (CrN film) were as follows.

Target: Cr target

Sputtering gas: a mixed gas of Ar and N₂ (Ar: 30 vol %, N₂: 70 vol %, gas pressure: 0.1 Pa)

Input power: 1,500 W

Film deposition rate: 7.8 nm/min

Film thickness: 5 nm

### Compositional Analysis of Hard Mask Layer 12 (CrN Film)

The composition of the hard mask layer 12 was measured by using an X-ray electron spectrometer by the same procedure as in Example 1. The compositional ratio (at %) of the hard mask layer 12 was Cr:N=41.5:58.5.

### Stress of Hard Mask Layer 12 (CrN Film)

The stress of the hard mask layer 12 was measured by the same method as in Example 1. It was confirmed that a very large compressive stress of −2,000 MPa is produced in the hard mask layer 12.

### Crystal State of Hard Mask Layer 12 (CrN Film)

The crystal state of the hard mask layer 12 was verified by the same method as in Example 1. A sharp peak was observed in the obtained diffraction peaks and therefore, the hard mask layer was confirmed to have a crystal structure.

### Surface Roughness of Hard Mask Layer 12 (CrN Film)

The surface roughness of the hard mask layer 12 was evaluated in the same manner as in Example 1, as a result, the surface roughness (rms) of the hard mask layer 12 was 0.55 nm.

### Adhesion of Hard Mask Layer 12 (CrN Film)

The adhesion of the hard mask layer 12 was evaluated in the same manner as in Example 1, as a result, peeling-off of squares occurred, revealing that the adhesion is insufficient. That is, it was confirmed that the film cannot sufficiently function as a hard mask layer of the blank for an imprint mold.

### Etching Properties of Hard Mask Layer 12 (CrN Film)

The etching properties of the hard mask layer 12 in dry etching process using a fluorine-based gas were evaluated in the same manner as in Example 1. The etching rate of the hard mask layer 12 (CrN film) was 2.0 nm/min. Since the etching rate of the SiO₂—TiO₂-based glass substrate without a hard mask layer 12 is 35 nm/min, the etching selectivity is 18, and due to this etching selectivity of less than 30, hard mask formation as a sufficiently thin film cannot be expected. In this case, when a case of etching the SiO₂—TiO₂-based glass by 100 nm for the production of a nanoimprint mold is envisaged, the required film thickness of the hard mask layer 12 (CrN film) calculated from the etching selectivity above becomes 5.6 nm.

While the present invention has been described in detail and with reference to specific embodiments thereof, it will be apparent to one skilled in the art that various changes and modifications can be made therein without departing from the spirit and scope of the invention.

This application is based on Japanese Patent Application No. 2012-010975 filed on Jan. 23, 2012, the contents of which are incorporated herein by way of reference.

### DESCRIPTION OF REFERENCE NUMERALS AND SIGNS

10: Blank for nanoimprint mold
11: Glass substrate
12: Hard mask layer
20: Resist
30: Nanoimprint mold
40: Master mold

1. A blank for a nanoimprint mold, comprising a glass substrate and a hard mask layer formed on said glass substrate, wherein:
said hard mask layer contains chromium (Cr) and nitrogen (N), and has a Cr content of from 45 to 95 at %, an N content of from 5 to 55 at % and a total content of Cr and N of 95 at % or more, and said hard mask layer has a film thickness of 1.5 nm or more and less than 5 nm.

2. The blank for a nanoimprint mold as described in claim 1, wherein:
said hard mask layer further contains hydrogen (H), and
said hard mask layer has the total content of Cr and N of from 95 to 99.9 at % and an H content of from 0.1 to 5 at %.

3. The blank for a nanoimprint mold as described in claim 1, wherein the crystal state of said hard mask layer is amorphous.

4. The blank for a nanoimprint mold as described in claim 1, wherein the etching electivity of said hard mask layer represented by (etching rate of glass substrate)/(etching rate of hard mask layer) is 30 to more.

5. The blank for a nanoimprint mold as described in claim 1, wherein said glass substrate is made of a dopant-free or dopant-containing quartz glass.

6. A nanoimprint mold produced by using the blank for a nanoimprint mold described in claim 1.

7. A method for producing a blank for a nanoimprint mold, containing a glass substrate and a hard mask layer formed on said glass substrate, wherein:
said hard mask layer contains chromium (Cr) and nitrogen (N), and has a Cr content of from 45 to 95 at %, an N content of from 5 to 55 at % and a total content of Cr and N of 95 at % or more, and
said method comprises forming said hard mask layer on said glass substrate by performing a sputtering process using a Cr target in an inert gas atmosphere containing argon (Ar) and nitrogen (N₂).

8. A method for producing a nanoimprint mold by using the blank for a nanoimprint mold described in claim 1, the method comprising a step of etching said hard mask layer of said blank for a nanoimprint mold by a dry etching process using a chlorine-based gas to form a pattern on said hard mask layer, and a step of etching said glass substrate by a dry etching process using a fluorine-based gas by employing, as a mask, the pattern formed on said hard mask layer.

9. A nanoimprint mold produced by the production method described in claim 8.
